(19) United States
(12) Patent Application Publication
(10) Pub. No.: US 2013/0228737 A1
(43) Pub. Date: Sep. 5, 2013

(54) NONVOLATILE SEMICONDUCTOR MEMORY DEVICE AND METHOD OF MANUFACTURING SAME

(71) Applicants: Hiroyuki FUKUMIZU, Yokohama-shi (JP); Yasuhiro Nojiri, Yokohama-shi (JP); Katsuyuki Sekine, Yokkaichi-shi (JP)

(72) Inventors: Hiroyuki FUKUMIZU, Yokohama-shi (JP); Yasuhiro Nojiri, Yokohama-shi (JP); Katsuyuki Sekine, Yokkaichi-shi (JP)

(73) Assignee: Kabushiki Kaisha Toshiba, Minato-ku (JP)

(21) Appl. No.: 13/601,494

(22) Filed: Aug. 31, 2012

(30) Foreign Application Priority Data
Sep. 22, 2011 (JP) 2011-208208

(51) Int. Cl. H01L 45/00

(52) U.S. Cl. CPC H01L 45/1253; H01L 45/16
USPC 257/4; 438/382

(57) ABSTRACT

According to an embodiment, a nonvolatile semiconductor memory device comprises memory cells in each of which are series-connected: a variable resistance element including a metal oxide; an electrode including a polysilicon layer and a SiGe layer formed between the polysilicon layer and the metal oxide; and a bipolar type current rectifying element.

### CROSS-REFERENCE TO RELATED APPLICATIONS

This application is based upon and claims the benefit of priority from the prior Japanese Patent Application No. 2011-208208, filed on Sep. 22, 2011, the entire contents of which are incorporated herein by reference.

### FIELD

The embodiments described herein relate to a nonvolatile semiconductor memory device and a method of manufacturing the same.

### BACKGROUND

### Description of the Related Art

Flash memory in which memory cells having a floating gate structure are NAND connected or NOR connected to configure a cell array is well known as a conventional electrically rewritable nonvolatile memory. In addition, ferroelectric memory is also known as a nonvolatile memory capable of being accessed randomly at high speed.

At the same time, resistance varying type memory that uses a variable resistance element for a memory cell is proposed as a technology for achieving further miniaturization of memory cells. The following are known as variable resistance elements, namely: a phase change memory element that has its resistance value changed by a change in state of crystallization/amorphousness of a chalcogenide compound; an MRAM element that employs resistance change due to a tunnel magneto-resistance effect; a polymer ferroelectric RAM (PFRAM) element that has a resistance element formed by a conductive polymer; a ReRAM element that has resistance change caused by an electrical pulse application; and so on.

Of these, the variable resistance elements used in ReRAM are broadly divided into those in which resistance change occurs due to presence/absence of charge trapped in a charge trap existing in an electrode interface, and those in which resistance change occurs due to presence/absence of a conductive path induced by oxygen deficiency or the like.

Moreover, there are two kinds of operation modes in the variable resistance elements used in ReRAM. One sets a high-resistance state and a low-resistance state by switching a polarity of an applied voltage, and this is called a bipolar type. The other allows a high-resistance state and a low-resistance state to be set by controlling a voltage value and a voltage application time without switching a polarity of an applied voltage, and this is called a unipolar type.

Even further miniaturization and increased storage capacity is expected from these kinds of variable resistance elements acting as cross-point type memory cells, hence increasingly low-power data write is desired.

### BRIEF DESCRIPTION OF THE DRAWINGS

FIG. 1 is a block diagram showing a configuration of a nonvolatile semiconductor memory device according to a first embodiment.

FIG. 2 is a perspective view of part of a memory cell array in the nonvolatile semi conductor memory device according to same embodiment.

FIG. 3 is a cross-sectional view of part of the memory cell array in the nonvolatile semi conductor memory device according to same embodiment.

FIG. 4 is a cross-sectional view showing a configuration of a memory cell in the nonvolatile semiconductor memory device according to same embodiment.

FIG. 5 is a schematic view for explaining an operation model of a nonvolatile semiconductor memory device according to a comparative example.

FIG. 6 is a schematic view for explaining the operation model of the nonvolatile semiconductor memory device according to the comparative example.

FIG. 7 is a view expressing a situation when a film of SiGe is formed under certain conditions.

FIG. 8 is a side view showing a method of manufacturing a nonvolatile semiconductor memory device according to the first embodiment.

FIG. 9 is a side view showing the method of manufacturing a nonvolatile semiconductor memory device according to same embodiment.

FIG. 10 is a side view showing the method of manufacturing a nonvolatile semiconductor memory device according to same embodiment.

FIG. 11 is a side view showing the method of manufacturing a nonvolatile semiconductor memory device according to same embodiment.

### DETAILED DESCRIPTION

A nonvolatile semiconductor memory device according to an embodiment comprises memory cells in each of which are series-connected: a variable resistance element including a metal oxide; an electrode including a polysilicon layer and a SiGe layer formed between the polysilicon layer and the metal oxide; and a bipolar type current rectifying element.

Embodiments of the nonvolatile semiconductor memory device are described below with reference to the drawings.

### First Embodiment

[Overall Configuration]

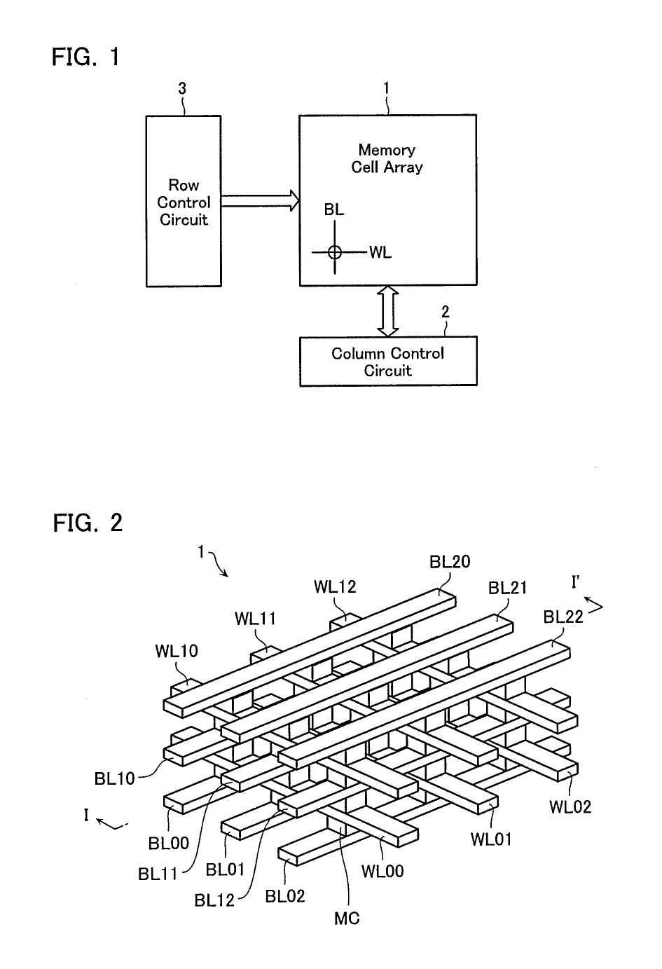

FIG. 1 is a block diagram showing a configuration of a nonvolatile semiconductor memory device according to a first embodiment. This nonvolatile semiconductor memory device comprises a memory cell array 1 having memory cells MC disposed in a matrix therein, each of the memory cells MC comprising a variable resistance element VR and a current rectifying element Di to be described later.

Electrically connected to bit lines BL of the memory cell array 1 is a column control circuit 2 for controlling the bit lines BL of the memory cell array 1 and enabling data erase of the memory cells MC, data write to the memory cells MC, and data read from the memory cells MC. Moreover, electrically connected to word lines WL of the memory cell array 1 is a row control circuit 3 for selecting the word lines WL of the memory cell array 1 and enabling data erase of the memory cells MC, data write to the memory cells MC, and data read from the memory cells MC.

[Memory Cell Array]

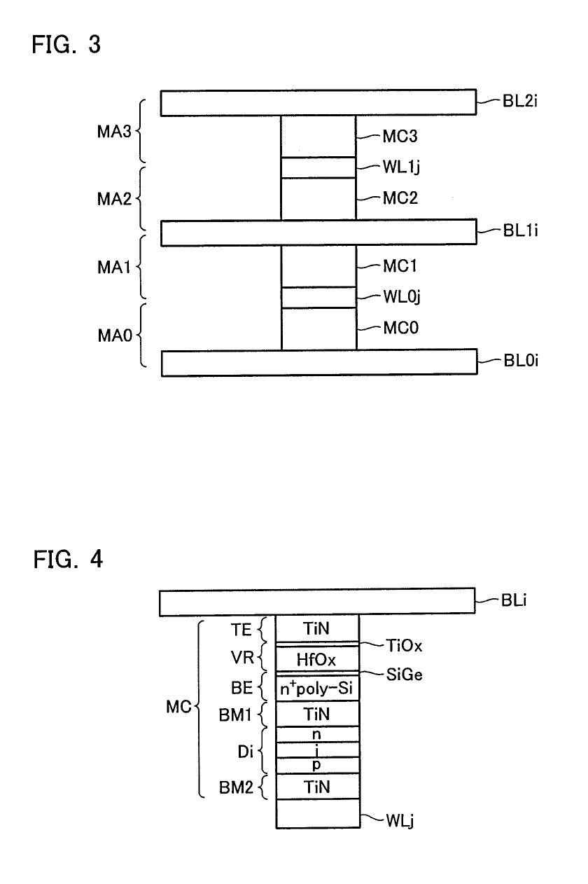

FIG. 2 is a perspective view of part of the memory cell array 1; FIG. 3 is a cross-sectional view of one column's worth of the memory cells MC taken along the line I-I′ and viewed in the direction of the arrows in FIG. 2; and FIG. 4 is a cross-sectional view of a single one of the memory cells MC. The memory cell array 1 is a cross-point type memory cell array, has a plurality of the word lines WL arranged in parallel therein, and a plurality of the bit lines BL arranged in parallel therein intersecting these word lines WL. One of the memory cells MC which are to be described later is disposed at each of intersections of the word lines WL and bit lines BL to be sandwiched by both lines. Memory cell arrays MA0-MA3 of this kind are formed in multiple layers sharing adjacent word lines WL and bit lines BL. Note that the word lines WL and bit lines BL preferably employ a material that is heat-resistant and has a low resistance value, for example, tungsten (W) , titanium (Ti) , tungsten nitride (WN) , titanium nitride (TiN) , tungsten silicide (WSi) , nickel silicide (NiSi) , cobalt silicide (CoSi) , or the like.

[Memory Cell]

As shown in FIG. 4, the memory cell MC comprises an upper electrode TE, the variable resistance element VR, a lower electrode BE, a barrier metal BM1, the current rectifying element Di, and a barrier metal B2, that are connected in series between the bit line BL and the word line WL.

The upper electrode TE and the barrier metals BM1 and BM2 in the present embodiment are formed from a TiN layer. This TiN layer can be formed by a method such as sputtering, and functions as a barrier metal layer and adhesive layer. Note that the upper electrode TE and the barrier metals BM1 and BM2 may also be formed by other metals such as Ti or the like.

The variable resistance element VR is formed by a HfOx layer of about 5 nm acting as a resistance varying film. A TiOx layer of about 8 Å is formed in a boundary between the HfOx layer and the upper electrode TE formed from TiN. Of these, the HfOx layer can be formed by a method such as ALD (Atomic Layer Deposition). Note that a film thickness of the HfOx layer is not limited to about 5 nm, but maybe changed appropriately in a range of about 2-10 nm. Moreover, in the present embodiment, HfOx is employed as the resistance varying film, but the following may also be adopted as the resistance varying film, namely, oxides of, for example, chromium (Cr), tungsten (W), vanadium (V) , niobium (Nb), tantalum (Ta), titanium (Ti), zirconium (Zr), hafnium (Hf), scandium (Sc), yttrium (Y), thorium (Tr), manganese (Mn), iron (Fe), ruthenium (Ru), osmium (Os), cobalt (Co), nickel (Ni) , copper (Cu) , zinc (Zn) , cadmium (Cd), aluminum (Al), gallium (Ga) , indium (In), tin (Sn) , lead (Pb), bismuth (Bi) , or oxides of, for example, the so-called rare earth elements from lanthanum (La) to lutetium (Lu), and so on.

In addition, the lower electrode BE is formed from an n type polysilicon layer and a SiGe layer formed in a boundary between this polysilicon layer and the HfOx layer. In the example shown in FIG. 4, when a setting operation described later or a read operation is performed, the lower electrode BE operates as a negative electrode, and when a resetting operation described later is performed, the lower electrode BE operates as a positive electrode. The following is considered to apply to the lower electrode BE: if too thick, its aspect ratio increases making processing of the memory cell difficult, and, moreover, its resistance increases; but if too thin, then, when film formation is performed by CVD, it grows in a striped shape, and, moreover, impurities escape; hence, it is formed in a total of about 5-30 nm for the two layers. In addition, 2-4 nm, and preferably about 2 nm, of an upper surface of the lower electrode BE is occupied by the SiGe layer. It is considered appropriate for the SiGe layer to be in the above-described range because a film thickness of about 2 nm of the SiGe layer results in sufficient seeds for crystallization, but if the SiGe layer is thickened, a risk of abnormal growth increases. A larger added amount of Ge in the SiGe layer results in better crystallization, but increases a risk of abnormal growth. Moreover, if Ge concentration is set high, then, since an oxide of Ge is water soluble, there is an increase in a side etching amount due to wet treatment and so on during cell processing, leading to a risk of a shape failure occurring . Therefore, the added amount of Ge in the SiGe layer should be set to about 5-40 atomic %. Ge may be included in the polysilicon layer but need not be included in the polysilicon layer. However, if Ge concentration in the polysilicon layer is high, then the risk of abnormal growth increases, and, moreover, since the film thickness of the polysilicon layer is greater than that of the layers above, the effect of side etching due to wet treatment and so on is large. Therefore, when Ge is included in the polysilicon layer, the concentration of Ge should be set lower than that of the SiGe layer, that is, to an amount at least half or less that of the SiGe layer. The polysilicon layer and the SiGe layer may be formed by the likes of reduced pressure CVD using SiH4 gas. Moreover, in the present embodiment, after causing the SiGe layer to grow on the polysilicon layer, annealing at substantially 650° C. is performed, whereby crystallization of Si and activation of dopants is performed. Ge functions to promote crystallization of Si, hence the above-described annealing process results in crystallization of both the polysilicon layer and the SiGe layer improving and resistivity falling.

In addition, the current rectifying element Di is formed as a NIP layer from an upper layer. Note that in the present embodiment, a diode is employed as the current rectifying element Di, but other ohmic elements such as a transistor may also be used.

[Operation of Memory Cell]

The nonvolatile semiconductor memory device according to the present embodiment is of a so-called bipolar type. Therefore, write of data to the memory cell MC is performed by applying for a certain time to a selected one of the memory cells MC a voltage corresponding to a breakdown voltage in a reverse direction of the current rectifying element Di. As a result, the variable resistance element VR in the selected memory cell MC changes from a high-resistance state to a low-resistance state. Hereinafter, this operation for changing the variable resistance element VR from a high-resistance state to a low-resistance state is called a “setting operation” . On the other hand, erase of data in the memory cell MC is performed by applying for a certain time to the variable resistance element VR in a low-resistance state after the setting operation a certain voltage in a forward direction of the current rectifying element Di. As a result, the variable resistance element VR changes from a low-resistance state to a high-resistance state. Hereinafter, this operation for changing the variable resistance element VR from a low-resistance state to a high-resistance state is called a “resetting operation”. For example, in the case of binary data storage, performing the resetting operation and setting operation on the selected memory cell MC is performed by changing a resistance state of the variable resistance element VR in the selected memory cell MC to a high-resistance state and low-resistance state, respectively. Moreover, forming needs to be performed on the variable resistance element VR when the variable resistance element VR is to be used. Forming also is performed by continuing to apply a certain voltage for a certain time, similarly to in the setting operation and resetting operation.

In the memory cell array 1 having the three-dimensional stacked arrangement as shown in FIG. 2, configuring peripheral circuits linked to the mutually intersecting bit lines BL and word lines WL such that the bit lines BL and word lines WL are provided specializing in different functions and omitting duplicated functions allows an area of the peripheral circuits to be more greatly reduced. This allows a memory device of smaller area for a given memory capacity to be realized, and is therefore desirable. As a result, a current rectifying direction in a current rectifying element Di in a memory cell MC positioned at an intersection of a bit line BL and a word line WL differs in the case that the bit line BL is positioned above the word line WL and the case that the bit line BL is positioned below the word line WL. It is desirable that the current rectifying element Di in a selected memory cell MC has current rectifying characteristics such that, for example, during resetting, current always flows from the word line WL toward the bit line BL, and, during setting, current always flows from the bit line BL toward the word line WL. In this case, upper and lower memory cells MC have a configuration where an order in each layer is reversed for the upper and lower memory cells MC.

[Operation Model of Variable Resistance Element]

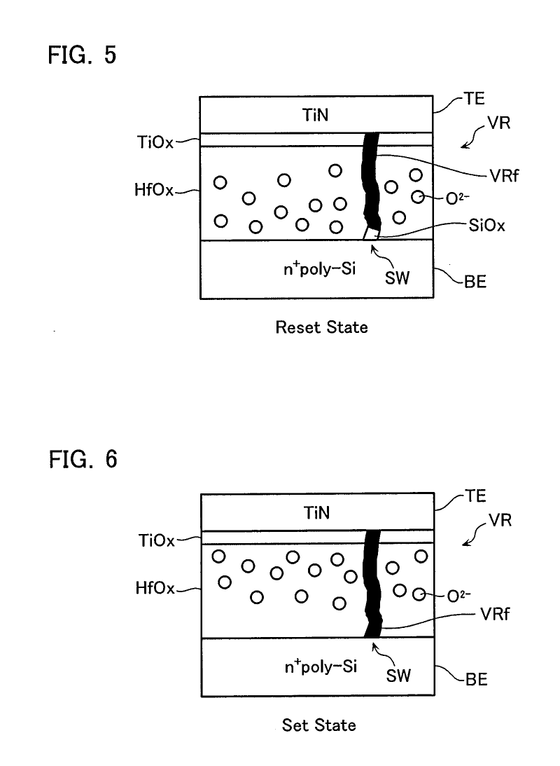

Next, an operation model of bipolar type ReRAM is described. FIGS. 5 and 6 are schematic views of part of the memory cell MC for explaining operation of a nonvolatile semiconductor memory device according to a comparative example, FIG. 5 showing a state of the variable resistance element VR in a reset state, and FIG. 6 showing a state of the variable resistance element VR in a set state. The lower electrode BE in the present embodiment has a two layer structure of a polysilicon layer and a SiGe layer, but a lower electrode BE in the comparative example is formed from a polysilicon layer only. Although an operating principle of bipolar type ReRAM is still unclear at present, a model of the following kind is supposed.

That is, as shown in FIGS. 5 and 6, when forming is performed in the variable resistance element VR, a filament VRf electrically connecting an upper electrode TE and the lower electrode BE is formed in the variable resistance element VR. A boundary between the filament VRf and the lower electrode BE configures a switching boundary SW that functions during the setting operation and resetting operation.

That is, the variable resistance element VR immediately after forming is in a low-resistance state (set state), but, by performing the resetting operation, changes to a high-resistance state (reset state). The resetting operation is performed by applying a voltage between the upper electrode TE and the lower electrode BE, setting the lower electrode BE to a high potential. As shown in FIG. 5, when a high potential is applied to the lower electrode BE, oxygen ions in the HfOx are attracted to a lower electrode BE side, whereby SiOx is formed in the switching boundary SW. In this way, the variable resistance element VR attains a high-resistance state (reset state) due to SiOx which is an insulating body being formed in the boundary between the resistance varying film and the lower electrode BE.

Moreover, the setting operation is performed, contrarily to the resetting operation, by applying a voltage between the upper electrode TE and the lower electrode BE, setting the upper electrode TE to a high potential. As shown in FIG. 6, when a high potential is applied to the upper electrode TE, oxygen in the SiOx is attracted to a HfOx layer side, whereby SiOx formed in the switching boundary SW is reduced, thereby causing the variable resistance element VR to attain a low-resistance state (set state).

[Setting Voltage]

The reason why a setting voltage in the comparative example is high and the reason why a setting voltage in the nonvolatile semiconductor memory device according to the present embodiment can be reduced are explained below based on the above-described operation model.

The lower electrode BE made of Si is formed by, for example, crystallizing-annealing, at about 650° C., Si and dopants formed by reduced pressure CVD or the like, but at a film thickness of 30 nm or less, there is a low probability that a nucleus for crystallization exists, and this results in insufficient crystallization and an increased resistance value. Therefore, voltage drop in a lower electrode BE portion increases and a voltage applied to the variable resistance element VR is reduced, and this is a first reason why the setting voltage is high.

In addition, the comparative example is configured such that the boundary between the variable resistance element VR and the lower electrode BE is formed by Si, the resetting operation causes SiOx to be formed in the switching boundary SW, and the setting operation causes oxygen to be withdrawn from the SiOx of the switching boundary SW. However, since SiOx is stable, it is difficult to withdraw oxygen from the SiOx, and this is a second reason linked to an increase in the setting voltage.

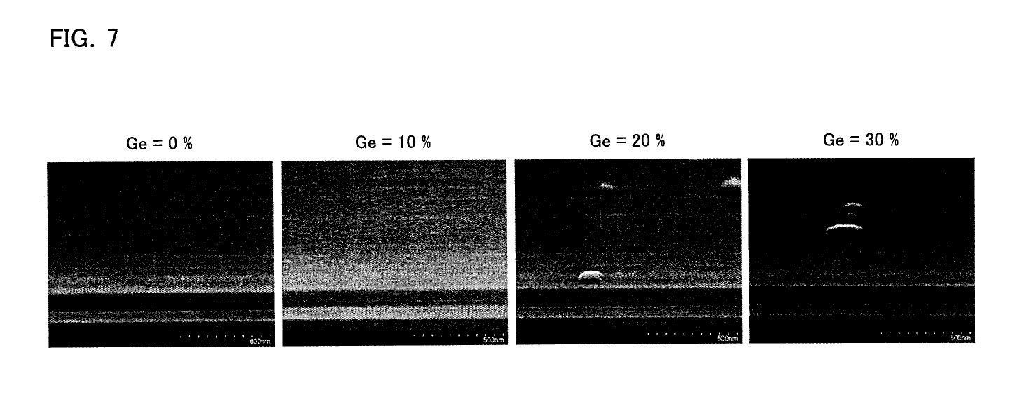

The first reason can be resolved by adding Ge to the Si lower electrode BE. When Ge is added to the Si, crystallization improves, hence the resistance value is reduced along with the added amount of Ge. However, there is a problem that if too much Ge is added to the Si, part of the crystal grain undergoes abnormal growth, causing a localized deterioration in roughness of the SiGe layer surface. FIG. 7 shows images of an SiGe film upper surface when added amount of Ge is changed in a range of 0-30%. It is found from FIG. 7 that if the added amount of Ge is 20% or more, the crystal grain in the SiGe upper surface undergoes abnormal growth. If a device is manufactured forming the likes of the variable resistance element VR on the basis of this kind of abnormal growth occurring in the crystal grain of the SiGe, then adverse effects are caused to the lithography processes, such as pattern formation defects, variation in element characteristics due to differences in film thickness, and so on. The greater the added amount of Ge, or the greater the film thickness, the easier it is for this kind of abnormal growth in the SiGe crystal grain to occur.

In view of the above points, the present embodiment adopts the two layer structure of the polysilicon layer and the SiGe layer for the lower electrode BE. The polysilicon layer is formed independently as a uniform film even when having a film thickness of several tens of nm and the SiGe layer is an extremely thin film (for example, 2 nm), hence these layers are capable of being formed as uniform well-crystallized films, without the crystal grain undergoing abnormal growth. Moreover, forming the SiGe layer in a layer above the polysilicon layer and then performing crystallizing-annealing enables crystallization of the polysilicon layer to be promoted while suppressing abnormal growth, and enables the resistance value of the entire lower electrode BE including the polysilicon layer and the SiGe layer to be lowered. Employing such a low-resistance electrode also enables voltage drop in the lower electrode BE during a write operation to be suppressed, thereby enabling lowering of setting voltage and suppression of resetting voltage increase.

In addition, the second reason is improved as below. That is, in the present embodiment, the SiGe layer exists in the boundary between the variable resistance element VR and the lower electrode BE acting as the positive electrode in the resetting operation, hence the resetting operation causes GeO2 and GeO to be formed in addition to SiOx.

Now, Gibbs standard generated energy at 1000K for Hf02, SiO2, Ge02, and GeO is, respectively, −895 kJ/mol, −726.9 kJ/mol, −397.1 kJ/mol, and −105.7 kJ/mol, making it clear that GeO2 and GeO are unstable substances compared to SiO2 and HfO2. This means that reducing GeO2 and GeO is easy, that is, requires only a low energy, compared to reducing SiO2. By thus providing SiGe between the variable resistance element VR and the lower electrode BE in this way, the present embodiment enables the setting voltage to be lowered.

When SiGe is employed as the lower electrode, the setting voltage decreases, and at the same time the resetting voltage increases. However, because in the resetting operation a voltage is applied to the memory cell MC in the forward direction, voltage drop in the current rectifying element Di is comparatively small. Therefore, the rise amount of the resetting voltage is small compared to the reduction amount of the setting voltage with respect to the comparative example, hence operating electric power of the nonvolatile semiconductor device overall is reduced.

Moreover, in the present embodiment, although GeO2 and GeO are thought to be formed in the switching boundary SW during the resetting operation, GeO2 and GeO have a small Gibbs standard generated energy and are thus unstable substances compared to SiO2, as mentioned above. Therefore, the possibility of a memory cell MC in a set state attaining a reset state regardless of the resetting operation not being performed in said memory cell MC is reduced, and data retention (data retaining characteristic) is thus improved.

Furthermore, in the nonvolatile semiconductor memory device according to the present embodiment, variations in setting voltage and resetting voltage are reduced compared to a conventional example. The reason for this is not understood at present, but it is thought to be due to an oxidation/reduction reaction becoming easier and improvement in crystallization.

[Method of Manufacturing]

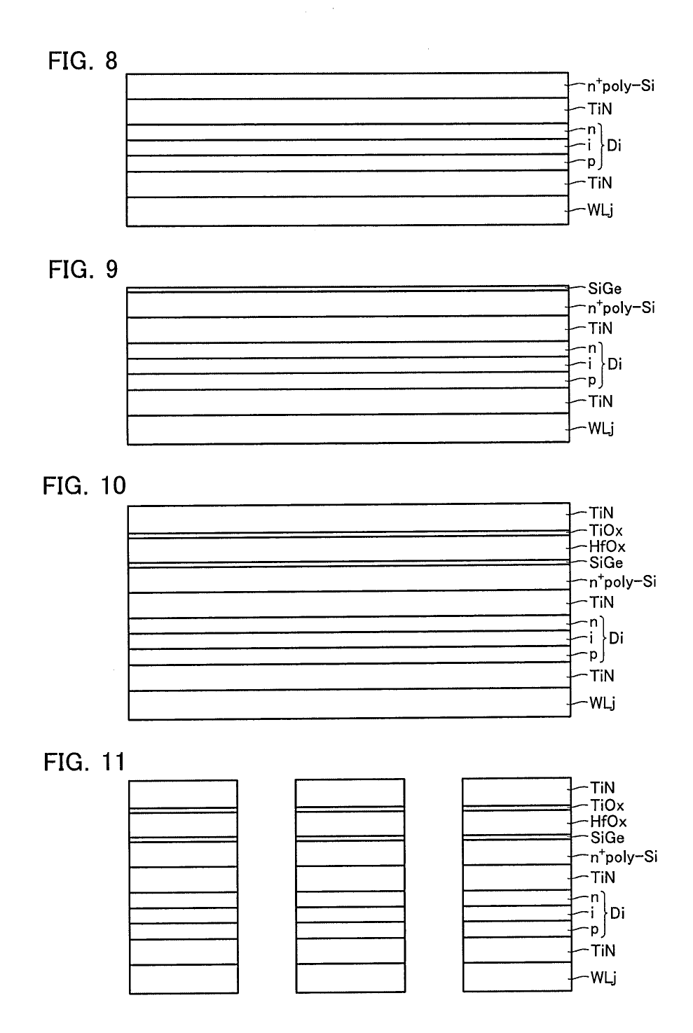

Next, a method of manufacturing a nonvolatile semiconductor memory device according to the present embodiment is described. As shown in FIG. 8, the nonvolatile semi conductor memory device according to the present embodiment has the following, namely: W (tungsten) that becomes the word line WL; TiN that becomes the barrier metal BM2; a p type semiconductor layer p, an i type semiconductor layer i, and an n type semiconductor layer n that become the current rectifying element Di; TiN that becomes the barrier metal BM1; and an n type polysilicon layer that forms part of the lower electrode BE, formed on a substrate not illustrated. Note that it is possible for film formation of the polysilicon layer to be performed by a method of reduced pressure CVD or the like.

Next, as shown in FIG. 9, an SiGe layer of about 2-4 nm, preferably about 2 nm, is caused to grow on the polysilicon layer. Note that in the present embodiment, a film thickness of the polysilicon layer and the SiGe layer is about 5-30 nm in total. In addition, an added amount of Ge in the SiGe layer may be set to about 5-40%. Moreover, the film thickness of the polysilicon layer is greater than that of the layers above, hence effects of side etching due to wet treatment and so on are large. Therefore, when Ge is included in the polysilicon layer, the concentration of Ge should be set lower than that of the SiGe layer, that is, to an amount at least half or less that of the SiGe layer. Subsequently, annealing at substantially 650° C. is performed on the stacked body formed, whereby crystallization of Si and activation of dopants is performed.

Next, as shown in FIG. 10, a HfOx layer of about 5 nm acting as the resistance varying film that becomes the variable resistance element VR is formed on the SiGe layer, and a TiN layer that becomes the upper electrode TE is formed on the HfOx layer via a TiOx layer. Next, as shown in FIG. 11, the stacked body formed undergoes separation by etching. Then, embedding of interlayer insulating films, formation of the bit lines BL and so on not illustrated are performed, thereby forming the memory cell array 1.

Note that only the memory cell MC1 layer portion is described in FIGS. 8-11, but that in reality a plurality of layers of memory cells can be formed. Moreover, manufacturing of the memory cells MC can be performed one layer at a time, or etching in the bit line direction and etching in the word line direction may also be performed simultaneously two layers at a time.

[Other]

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising memory cells in each of which are series-connected:
a variable resistance element including a metal oxide;
an electrode including a polysilicon layer and a SiGe layer formed between the polysilicon layer and the metal oxide; and
a bipolar type current rectifying element.

2. The nonvolatile semiconductor memory device according to claim 1, including:
first lines; and
second lines intersecting the first lines,
wherein the memory cells are connected between the first lines and the second lines.

3. The nonvolatile semiconductor memory device according to claim 1, wherein
the polysilicon layer includes Ge,
a concentration of Ge in the SiGe layer is two or more times higher than a concentration of Ge in the polysilicon layer.

4. The nonvolatile semiconductor memory device according to claim 1, wherein
5-40 atomic % of Ge is included in the SiGe layer.

5. The nonvolatile semiconductor memory device according to claim 1, wherein
a film thickness of the SiGe layer is 2-4 nm.

6. The nonvolatile semiconductor memory device according to claim 1, wherein
a film thickness of the electrode is 5-30 nm.

7. The nonvolatile semiconductor memory device according to claim 1, wherein
the SiGe layer is connected to a surface of the variable resistance element acting as a negative electrode in a setting operation and acting as a positive electrode in a resetting operation.

8. A nonvolatile semiconductor memory device including a plurality of memory cell arrays that are stacked, the memory cell arrays each including: first lines; second lines intersecting the first lines; and memory cells connected between the first lines and the second lines, the memory cells each having series-connected therein:
a variable resistance element including a metal oxide;
an electrode including a polysilicon layer and a SiGe layer formed between the polysilicon layer and the metal oxide; and
a bipolar type current rectifying element,
the electrode being connected to a surface of the variable resistance element acting as a negative electrode in a setting operation and acting as a positive electrode in a resetting operation.

9. The nonvolatile semiconductor memory device according to claim 8, wherein
upper and lower neighboring memory cells share the first lines or the second lines.

10. The nonvolatile semiconductor memory device according to claim 8, wherein
the polysilicon layer includes Ge,
a concentration of Ge in the SiGe layer is two or more times higher than a concentration of Ge in the polysilicon layer.

11. The nonvolatile semiconductor memory device according to claim 8, wherein
5-40 atomic % of Ge is included in the SiGe layer.

12. The nonvolatile semiconductor memory device according to claim 8, wherein
a film thickness of the SiGe layer is 2-4 nm.

13. The nonvolatile semiconductor memory device according to claim 8, wherein
a film thickness of the electrode is 5-30 nm.

14. A method of manufacturing a nonvolatile semiconductor memory device, the nonvolatile semiconductor memory device including: a substrate, first lines; second lines intersecting the first lines;
and memory cells connected between the first lines and the second lines, each of the memory cells being configured to have series-connected therein: a variable resistance element including a metal oxide; an electrode including a polysilicon layer; and a bipolar type current rectifying element, the method comprising:
forming a conductive layer on the substrate, the conductive layer forming the first lines;
forming a current rectifying layer, the current rectifying layer forming the current rectifying element;
forming a polysilicon layer, the polysilicon layer forming a lower part of the electrode;
forming a SiGe layer forming an upper part of the electrode on the polysilicon layer; and
performing annealing on a stacked body that includes the substrate, the conductive layer, the current rectifying layer, the polysilicon layer, and the SiGe layer.

15. The method of manufacturing a nonvolatile semiconductor memory device according to claim 14, wherein
a temperature of the annealing is substantially 650° C.

16. The method of manufacturing a nonvolatile semiconductor memory device according to claim 15, wherein
the polysilicon layer includes Ge,
a concentration of Ge in the SiGe layer is two or more times higher than a concentration of Ge in the polysilicon layer.

17. The method of manufacturing a nonvolatile semiconductor memory device according to claim 15, wherein
5-40 atomic % of Ge is included in the SiGe layer.

18. The method of manufacturing a nonvolatile semiconductor memory device according to claim 15, wherein
a film thickness of the SiGe layer is 2-4 nm.

19. The method of manufacturing a nonvolatile semiconductor memory device according to claim 15, wherein
a film thickness of the electrode is 5-30 nm.

20. The method of manufacturing a nonvolatile semiconductor memory device according to claim 15, wherein
the SiGe layer is connected to a surface of the variable resistance element acting as a negative electrode in a setting operation and acting as a negative electrode in a resetting operation.
